(19) United States
(12) Patent Application Publication
(10) Pub. No.: US 2022/0367329 A1
(43) Pub. Date: Nov. 17, 2022

(54) CONTACT ASSEMBLY FOR AN ELECTRONIC COMPONENT, AND METHOD FOR PRODUCING AN ELECTRONIC COMPONENT

(71) Applicant: Vitesco Technologies GmbH, Regensburg (DE)

(72) Inventors: Detlev Bagung, Munich (DE); Christian Lammel, Munich (DE); Juergen Luttner, Munich (DE)

(21) Appl. No.: 17/765,750

(22) PCT Filed: Oct. 7, 2020
(86) PCT No.: PCT/EP2020/078031

§ 371 Date: Mar. 31, 2022

(30) Foreign Application Priority Data
Oct. 9, 2019 (DE) 10 2019 215 471.9

(51) Int. Cl. H01L 23/498; H01L 21/48; H01L 23/00; H01R 12/52

(52) U.S. Cl. CPC H01L 23/49811; H01L 23/49822; H01L 21/4853; H01L 21/4857; H01L 24/48; H01L 24/49; H01L 24/85; H01R 12/52; H01L 23/49838; H01L 2224/48091; H01L 2224/48105; H01L 2224/48229; H01L 2224/4903; H01L 2224/85214; H01L 2224/858; H01R 4/029

(57) ABSTRACT

A contact assembly for an electronic component includes a wiring substrate having an upper face, a lower face and at least one contact connection surface on the upper face. At least one bonding strip is provided for connection to the at least one contact connection surface. The at least one contact connection surface is disposed on at least one metal-filled recess in the volume of the wiring substrate. A semiconductor component, an electronic component and a method for producing an electronic component are also provided.

The present invention relates to a contact assembly for an electronic component. It also relates to a method for producing an electronic component.

Methods for electrically contacting multi-layer substrates are known from US 2012/0133052 A1, U.S. Pat. No. 7,164,572 B1, EP 1 560 267 A1 and US 2017/0221814 A1.

Bonding strips are sometimes used for the contacting of semiconductor parts of a semiconductor component, in particular power semiconductor parts, and have a particularly high current carrying capacity in comparison to bonding wires. Bonding strips are often also used for contacting wiring substrates with one another, for example PCB to PCB or between lead frames. Bonding strips of this kind have an approximately rectangular cross section and additionally a width which considerably exceeds the thickness of the bonding strip. Bonding strips of this kind can be connected, for example, by means of laser welding to contact connection surfaces of a wiring substrate, for example of a PCB. The contact connection surfaces on the substrate, which typically are formed from copper, must be relatively thick here in order to take up the necessary process energy and prevent premature damage to the wiring substrate. Thicker copper layers of the wiring substrate, however, increase the overall costs for the wiring substrate. In addition, in the case of thick copper layers, larger clearances have to be provided on the circuit board, and therefore it is difficult to provide certain layouts on the circuit board.

An object of the present invention is to describe a contact assembly for an electronic component which allows the contacting of a contact connection surface of a wiring substrate with a bonding strip in a particularly simple and cost-effective way. Furthermore, the intention is to specify a method for producing an electronic component having a contact assembly of this kind.

This object is achieved by means of the subject matter of the independent claims. The dependent claims relate to advantageous embodiments and developments.

According to one aspect of the invention, a contact assembly for an electronic component is described, which has at least one bonding strip for connecting to a contact connection surface of a wiring substrate. Furthermore, the contact assembly has a wiring substrate with an upper face and a lower face, wherein a contact connection surface for contacting the bonding strip is provided at least on the upper face of the wiring substrate, wherein the contact connection surface is arranged on at least one metal-filled recess in the volume of the wiring substrate.

The contact assembly has the advantage that the metal thickness which takes up the welding energy is increased merely locally and thus particularly efficiently by the at least one metal-filled recess beneath the contact connection surfaces. Sufficient metal, in particular copper, is thus available beneath the contact connection surface in order to take up the process energy, wherein, however, there is also no need to reinforce the conductor track thickness of the wiring substrate. A contact assembly of this kind thus allows for a utilization of the process energy required for the ribbon bonding and is additionally producible cost-effectively due to the merely locally increased metal quantity.

A bonding strip in the present context is understood in particular to mean a metal strip which is intended for the—in particular integrally bonded—connection to the contact connection surface and the width of which is at least 4 times as great, for example at least 8 times as great, as its height. Here, when the contact assembly is in the assembled state, the width is the dimension parallel to the contact connection surface and perpendicular to the main direction of extent of the bonding strip in its elongate state, and the height is the direction along the surface normal of the contact assembly.

According to one embodiment of the invention, the recess tapers, in particular in the direction away from the contact connection surface. For example, the recess is typically conical in the longitudinal section, wherein its greatest diameter is directly beneath the contact connection surface. The term “conical” in this case also includes recesses with a frustoconical longitudinal section.

Here, a longitudinal section is understood to mean a section through the recess, perpendicularly to the upper face of the wiring substrate. The fact that the largest diameter of the recess is directly beneath the contact connection surface means that the tip of the cone or cone frustum formed by the recess points away from the upper face of the wiring substrate in the direction of a lower face of the substrate.

A geometry of this kind of the recess is made by laser drilling as a production method for the recess. As has been proven, laser drilling is a particularly efficient way of producing recesses of this kind. Laser-drilled recesses, however, can also have geometries deviating from the (typical) cone shape, and in some circumstances can be cylindrical or almost spherical.

According to one embodiment, the wiring substrate is multi-layered and a plurality of metal-filled recesses arranged one above the other are arranged beneath the contact connection surface, in the volume of the wiring substrate, in such a way that they are interconnected.

A wiring substrate of this kind is produced by successive build-up of a plurality of layers and allows on the one hand the production of also more complex rewiring topologies and on the other hand the production of relatively thick metal fillings in order to take up high process energies.

According to one embodiment, a plurality of adjacently arranged, metal-filled recesses is arranged beneath the contact connection surface, in the volume of the wiring substrate, in such a way that they are interconnected.

In a contact assembly of this kind, relatively broad, i.e. not only circular, but also widened contact connection surfaces are provided, which is advantageous in particular for strip bonding. Metal-filled recesses can be provided across the entire width of the contact connection surfaces, beneath the contact connection surface, to take up the process energy. The number of adjacently arranged, metal-filled recesses is dependent here on the width of the contact connection surface, which is in turn dependent on the width of the used bonding strip.

The metal filling of the at least one recess comprises copper in particular, or consists of copper.

According to one embodiment, an upper face of the metal-filled recess is formed flush with the upper face of the wiring substrate surrounding said recess.

In a further embodiment, the contact assembly has a metal layer, which contains the contact connection surface and covers at least the upper face of the metal-filled recess. In this embodiment it is provided that the metal layer with the contact connection surface is applied as a separate layer to the upper face of the wiring substrate and is thus provided as a separate layer on the metal-filled recess.

According to one embodiment, the bonding strip is connection to the at least one contact connection surface by means of a laser welded connection. Laser welding is usually used as a connection technique for ribbon bonding (strip bonding).

The metal-filled recess can be covered expediently on its side opposite the contact connection surface by an electrically insulating layer, which in a development is formed by a carrier material of the wiring substrate. According to one embodiment, the lower face of the wiring substrate is formed by an electrically insulating layer, that is to say a fully closed electrically insulating layer.

An embodiment of this kind is advantageous in particular in the case of power semiconductor components if a metal heat sink for dissipating heat is to be mounted on the lower face of the wiring substrate. In this embodiment the metal recesses of the wiring substrate do not penetrate through fully.

According to one aspect of the invention, a semiconductor component having the described contact assembly is described, wherein a semiconductor part is arranged on the upper face of the wiring substrate and has at least one contact connection surface, which is connected by means of at least one bonding strip to a contact connection surface of the wiring substrate.

The semiconductor part can be, in particular, a power semiconductor part. The wiring substrate is, for example, a circuit board, in particular a printed circuit board (PCB), for example a multi-layer circuit board. In these cases, the semiconductor component can be a circuit board assembly.

According to a further aspect, an electronic component is described which comprises the wiring substrate and at least one further wiring substrate, wherein a contact connection surface of the further wiring substrate is connected to a contact connection surface of the wiring substrate by means of the at least one bonding strip.

According to one aspect of the invention, a method for producing an electronic component is described, which comprises providing a wiring substrate having an upper face and a lower face, wherein the wiring substrate has a matrix formed of an electrically insulating material and also conductor track structures embedded therein. The method further includes making recesses in the wiring substrate by means of laser drilling from the upper side and also introducing a metal filling into the recesses.

The method also comprises applying contact connection surfaces to the upper faces of the metal fillings and also connecting contact connection surfaces of a semiconductor part or a further wiring substrate to the contact connection surfaces of the wiring substrate by means of a bonding strip.

The method has the advantages already described in conjunction with the contact assembly.

According to one embodiment, the steps of providing the wiring substrate, making recesses in the wiring substrate by means of laser drilling from the upper face, and also introducing a metal filling into the recesses are performed repeatedly in succession to form a multi-layer wiring substrate.

Once a multi-layer wiring substrate has been formed in this way, the at least one semiconductor part can be placed on the uppermost layer. The contact connection surfaces are likewise mounted on the uppermost layer.

The recesses are made in particular by means of laser drilling or mechanical drilling.

Contact connection surfaces of the semiconductor part are connected by means of the bonding strip to the contact connection faces of the wiring substrate, in particular by means of laser welding.

Embodiments of the invention will be described by way of example below with reference to schematic drawings.

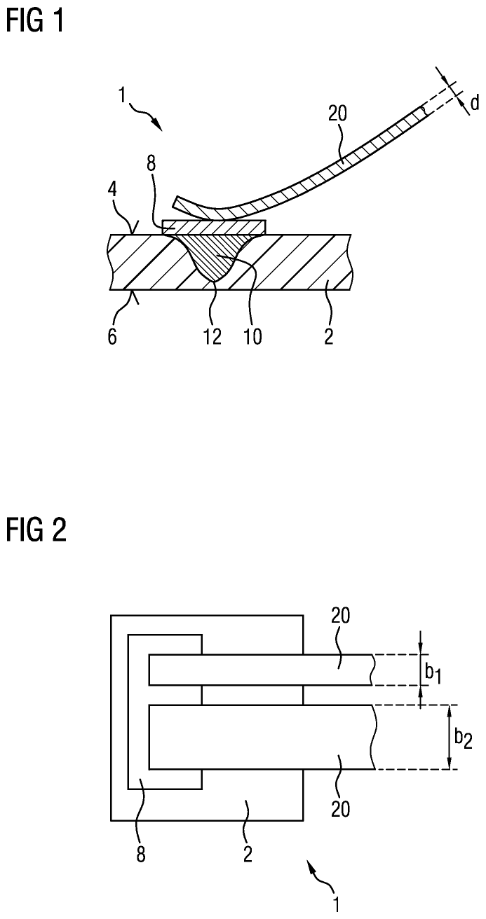

FIG. 1 shows a sectional illustration of a contact assembly as per a first embodiment of the invention;

FIG. 2 shows a plan view of the contact assembly device as per FIG. 1;

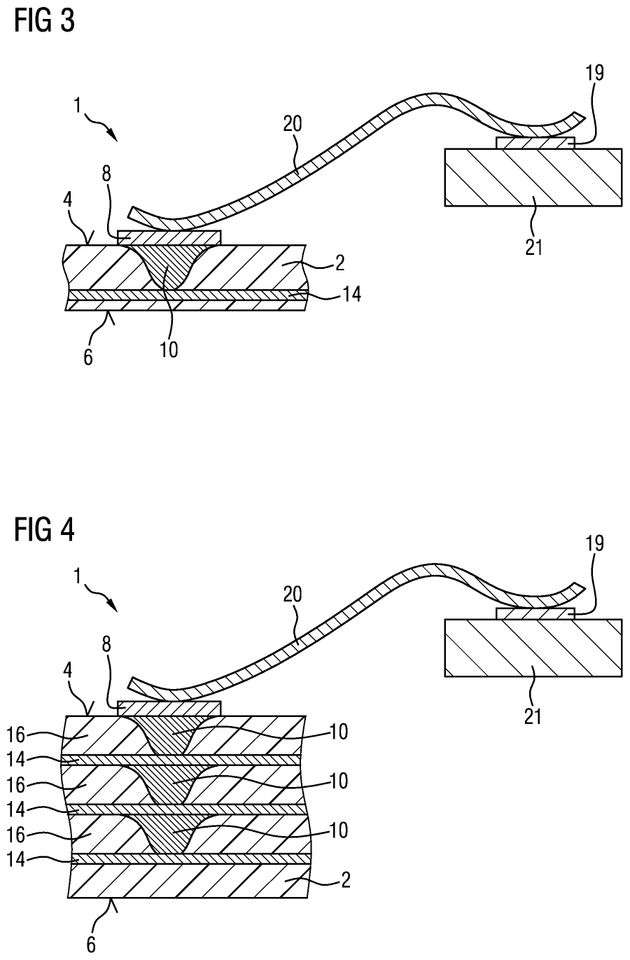

FIG. 3 shows a sectional view of a contact assembly as per a second embodiment of the invention;

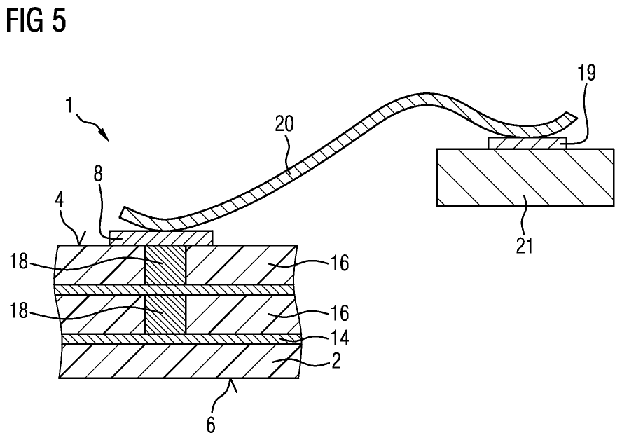

FIG. 4 shows a sectional view of a contact assembly as per a third embodiment of the invention;

FIG. 5 shows a sectional view of a contact assembly as per a fourth embodiment of the invention;

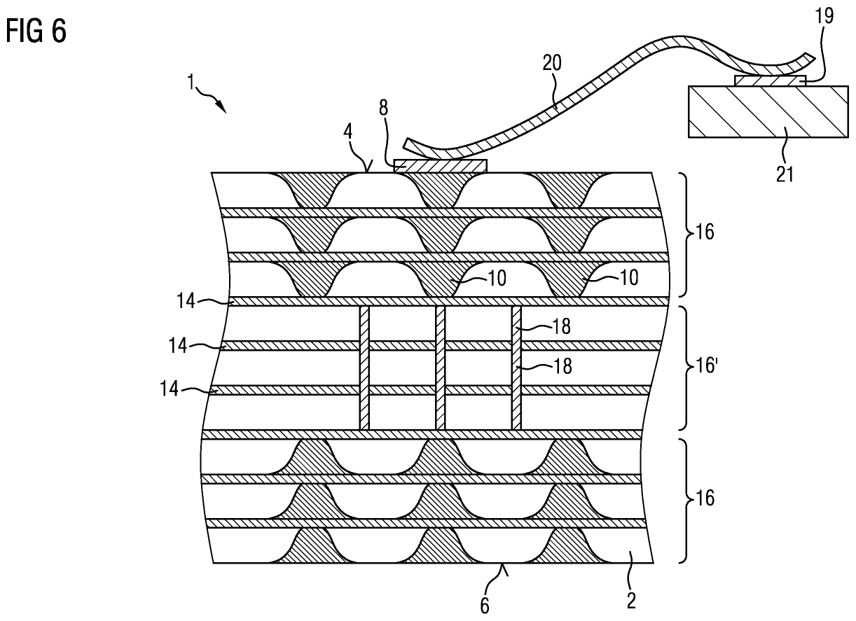

FIG. 6 shows a sectional view of a contact assembly as per a fifth embodiment of the invention; and

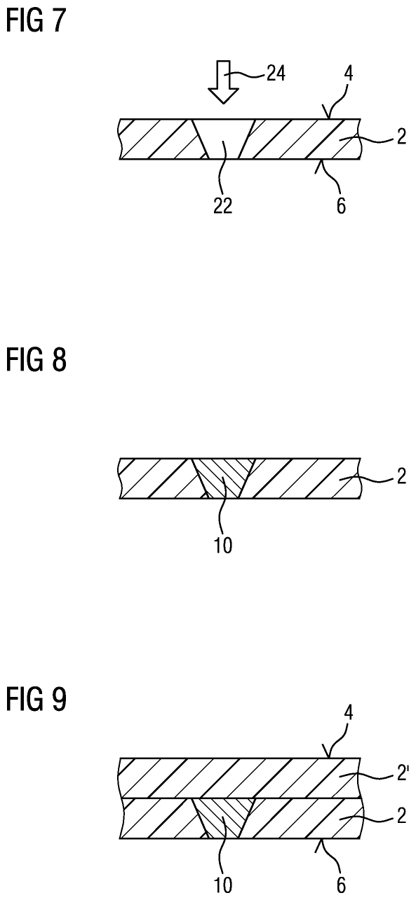

FIGS. 7-11 show steps of a method for producing a contact assembly as per an embodiment of the invention.

FIG. 1 shows a contact assembly for a semiconductor component, in particular, but not only, for a power semiconductor component, and/or for an electronic component comprising at least two interconnected wiring substrates. The contact assembly 1 comprises a wiring substrate 2 with an upper face 4 and a lower face 6 opposite the upper face 4. At least one contact connection surface 8 is arranged on the upper face 4 of the wiring substrate 2 and is electrically contacted by means of at least one bonding strip 20.

The contact connection surface 8 is arranged on a metal-filled recess 10 which is formed in the wiring substrate 20. The metal-filled recess 10, in the first embodiment shown in FIG. 1, has a cone shape, wherein the tip 12 of the cone is directed away from the upper face 4 in the direction of the lower face 6, so that the base area of the cone forms part of the upper face 4 of the wiring substrate 2. The contact connection surface 8 is formed on this base area.

FIG. 2 shows a plan view of the contact assembly 1 as per FIG. 1. In this view, it can be seen that the bonding strips 20, two of which are shown in this view bonded adjacently on the contact connection surface 8, have a relatively large width b₁, b₂. The widths b₁, b₂ are in particular several times greater than a thickness d of the bonding strips 20.

In this embodiment, the contact connection surface 8 has a rectangular shape. In order to absorb across its entire width the heat that is produced during the bonding process, a plurality of recesses 10 are arranged adjacently beneath the contact connection surface 8. In this way, the heat created when bonding a plurality of adjacently bonded bonding strips, of which also three or more can be provided, can be taken up.

FIG. 3 shows a contact assembly 1 according to a second embodiment. This differs from the embodiment shown in FIG. 1 in that at least one electrically conductive layer 14 is provided in the wiring substrate 2. In the shown embodiment the electrically conductive layer 14 is not exposed on the lower face 6 of the wiring substrate 2, but instead an electrically insulating material is provided.

In the embodiment shown in FIG. 3, the metal-filled recess 10 reaches as far as the electrically conductive layer 14 and contacts the latter. In this way, the electrically conductive layer 14 is likewise used to dissipate and spread heat. Depending on the layout of the wiring substrate 2, however, it can also be advantageous to avoid electrical contact between the metal-filled recess 10 and the electrically conductive layer 14. In such a case, the metal-gilled recess 10 ends above the electrically conductive layer 14.

FIG. 4 shows a contact assembly 1 according to a third embodiment. This differs from the second embodiment shown in FIG. 3 in that the wiring substrate 2 has a plurality of wiring layers 16. In order to be able to dissipate heat particularly efficiently, metal-filled recesses 10 are arranged in each wiring layer 16, more specifically in such a way that the recesses are arranged stacked beneath the contact connection surfaces 8. In this way, heat can be taken up by the contact connection surface 8 and can be dissipated and distributed via a plurality of layers.

FIG. 5 shows a fourth embodiment of the contact assembly 1, which differs from that shown in FIG. 4 in that the metal-filled recesses 18 are not conical, but cylindrical. Such geometries of metal-filled recesses 18 can be produced in particular by mechanical drilling.

FIG. 6 shows a contact assembly 1 as per a fifth embodiment of the invention. According to this embodiment, the wiring substrate 2 is formed from a plurality of layers 16, 16′, which each have different metal-filled recesses 10, 18. The metal-filled recesses 10, 18 can be used here both to for electrically contacting and for heat dissipation.

In the embodiment shown in FIG. 6, metal-filled recesses 10 are exposed at the lower face 6 of the wiring substrate 2. This can be problematic in some circumstances, if the wiring substrate 2 is to be applied directly to a heat sink without contacting this electrically. In this case, an insulating layer can be introduced between the wiring substrate 2 and the heat sink.

Subjacent recesses 10, 18 in FIGS. 4 to 6 can be filled, as shown, with a metal; they can also be unfilled.

FIGS. 7-11 show steps of a method for producing a wiring substrate 2 for a contact assembly 1.

FIG. 7 shows a wiring substrate 2 with an upper face 4 and a lower face 6 arranged opposite, wherein a recess 22 is made in the wiring substrate from the upper face 4. The recess 22 is made by means of laser drilling, which is symbolized by the arrow 24. The method of laser drilling results typically, but not necessarily, in a conical or frustoconical geometry of the recess 22.

FIG. 8 shows the wiring substrate 2 once a metal filling has been introduced into the recess 22 to form a metal-filled recess 10.

FIG. 9 shows the wiring substrate 2 once a further layer 2′ has been applied to the upper face 4 of the wiring substrate 2.

FIG. 10 shows the making of a recess 22 in the further layer 2′ from the upper face 4′ by means of laser drilling. In FIG. 10 an inner contact connection surface 80, or what is known as an inner layer path, is also shown by dashed lines. Inner contact connection surfaces 80 of this kind can also be integrated into the wiring substrate 2.

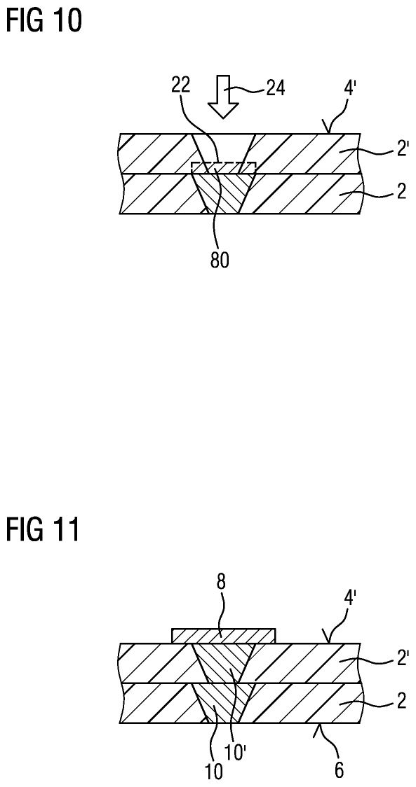

FIG. 11 shows the wiring substrate 2, 2′ once a metal contact connection surface 8 has been applied to the metal-filled recesses 10′, 10.

With the method described with reference to FIGS. 7-11, it is possible to produce multi-layer wiring substrates 2, as are also shown in FIGS. 4-6.

1-15. (canceled)

16. A contact assembly for an electronic component, the contact assembly comprising:
a wiring substrate including an upper face, a lower face and a volume having at least one metal-filled recess formed therein;
said wiring substrate having at least one contact connection surface provided at least on said upper face, said at least one contact connection surface disposed on said at least one metal-filled recess formed in said volume; and
at least one bonding strip connected to said at least one contact connection surface.

17. The contact assembly according to claim 16, which further comprises an electrically insulating layer covering a side of said metal-filled recess disposed opposite to said at least one contact connection surface.

18. The contact assembly according to claim 16, wherein said metal-filled recess tapers into a conical shape and has a greatest diameter directly beneath said at least one contact connection surface.

19. The contact assembly according to claim 18, wherein said metal-filled recess tapers in a longitudinal section.

20. The contact assembly according to claim 16, wherein:
said wiring substrate is multi-layered; and
said at least one metal-filled recess includes a plurality of metal-filled recesses being interconnected and disposed above one another beneath said at least one contact connection surface in said volume of said wiring substrate.

21. The contact assembly according to claim 16, wherein said at least one metal-filled recess includes a plurality of interconnected, adjacently disposed, metal-filled recesses disposed beneath said at least one contact connection surface in said volume of the wiring substrate.

22. The contact assembly according to claim 16, wherein said at least one metal-filled recess has a metal filling including copper or consisting of copper.

23. The contact assembly according to claim 16, wherein said at least one metal-filled recess has an upper face being at least one of:
formed flush with said upper face of said wiring substrate surrounding said at least one metal-filled recess, or
covered with a metal layer having said at least one contact connection surface.

24. The contact assembly according to claim 16, which further comprises a laser welded connection interconnecting said bonding strip and said at least one contact connection surface.

25. The contact assembly according to claim 16, wherein said lower face of said wiring substrate is formed of an electrically insulating layer.

26. A semiconductor component, comprising:
a contact assembly according to claim 16; and
at least one semiconductor part having at least one contact connection surface connected by said at least one bonding strip to said contact connection surface of said wiring substrate disposed on said upper face of said wiring substrate.

27. The semiconductor component according to claim 26, wherein said at least one semiconductor part is a power semiconductor part.

28. An electronic component, comprising:
a contact assembly according to claim 16; and
at least one further wiring substrate having a contact connection surface connected by said at least one bonding strip to said contact connection surface of said wiring substrate.

29. A method for producing an electronic component according to claim 28, the method comprising:
providing a wiring substrate having an upper face, a lower face and a matrix formed of an electrically insulating material and conductor track structures embedded in the electrically insulating material;
introducing recesses into the wiring substrate by laser drilling or mechanical drilling from the upper face;
introducing a metal filling into the recesses to form metal-filled recesses;
applying contact connection surfaces to the upper faces of the metal fillings; and
using at least one bonding strip to connect contact connection surfaces of a semiconductor part or a further wiring substrate to the contact connection surfaces.

30. The method according to claim 29, which further comprises forming a multi-layer wiring substrate by successively repeatedly performing the steps of providing the wiring substrate, introducing the recesses into the wiring substrate by laser drilling or mechanical drilling from the upper face, and introducing the metal filling into the recesses.

31. The method according to claim 29, which further comprises using the bonding strip to connect the contact connection surfaces of the semiconductor part or of the further wiring substrate to the contact connection surfaces by laser welding.
